(19) United States
(12) Patent Application Publication
(10) Pub. No.: US 2017/0005030 A1
(43) Pub. Date: Jan. 5, 2017

(54) Flat No-Leads Package With Improved Contact Pins

(71) Applicant: Microchip Technology Incorporated, Chandler, AZ (US)

(72) Inventors: Rangsun Kitnarong, Bangkeng Muang (TH); Prachit Punyapor, Amphur Thanyaburi (TH); Ekgachai Kenganantanon, Nonthaburi (TH)

(73) Assignee: Microchip Technology Incorporated, Chandler, AZ (US)

(21) Appl. No.: 15/263,030

(22) Filed: Sep. 12, 2016

Related U.S. Application Data
(62) Division of application No. 14/945,679, filed on Nov. 19, 2015.
(60) Provisional application No. 62/082,357, filed on Nov. 20, 2014.

(51) Int. Cl. H01L 23/495; H01L 21/56; H01L 21/78; H01L 23/31; H01L 21/66; H01L 21/288; H05K 3/34; H01L 23/00; H01L 21/48

(52) U.S. Cl. CPC H01L 23/49541; H01L 24/83; H01L 21/561; H01L 21/78; H01L 21/4842; H01L 24/97; H01L 22/14; H01L 24/85; H01L 24/92; H01L 21/288; H05K 3/3442; H05K 3/3494; H01L 23/3114; H01L 2224/48091; H01L 2224/48106; H01L 2224/48247; H01L 2224/73265; H01L 2224/32245; H01L 2224/92247

(57) ABSTRACT

According to an embodiment of the present disclosure, a leadframe for an integrated circuit (IC) device may comprise a center support structure for mounting an IC chip, a plurality of pins extending from the center support structure, and a bar connecting the plurality of pins remote from the center support structure. Each pin of the plurality of pins may include a dimple.

### RELATED PATENT APPLICATION

This application claims priority to commonly owned U.S. Provisional Patent Application No. 62/082,357, filed Nov. 20, 2014, which is hereby incorporated by reference herein for all purposes.

### TECHNICAL FIELD

The present disclosure relates to integrated circuit packaging, in particular to so-called flat no-leads packaging for integrated circuits.

### BACKGROUND

Flat no-leads packaging refers to a type of integrated circuit (IC) packaging with integrated pins for surface mounting to a printed circuit board (PCB). Flat no-leads may sometimes be called micro leadframes (MLF). Flat no-leads packages, including for example quad-flat no-leads (QFN) and dual-flat no-leads (DFN), provide physical and electrical connection between an encapsulated IC component and an external circuit (e.g., to a printed circuit board (PCB)).

In general, the contact pins for a flat no-leads package do not extend beyond the edges of the package. The pins are usually formed by a single leadframe that includes a central support structure for the die of the IC. The leadframe and IC are encapsulated in a housing, typically made of plastic. Each leadframe may be part of a matrix of leadframes that has been molded to encapsulate several individual IC devices. Usually, the matrix is sawed apart to separate the individual IC devices by cutting through any joining members of the leadframe. The sawing or cutting process also exposes the contact pins along the edges of the packages.

Once sawn, the bare contact pins may provide bad or no connection for reflow soldering. The exposed face of contact pins may not provide sufficient wettable flanks to provide a reliable connection. Reflow soldering is a preferred method for attaching surface mount components to a PCB, intended to melt the solder and heat the adjoining surfaces without overheating the electrical components, and thereby reducing the risk of damage to the components.

### SUMMARY

Hence, a process or method that improves the wettable surface of flat no-leads contact pins for a reflow soldering process to mount the flat no-leads package to an external circuit may provide improved electrical and mechanical performance of an IC in a QFN or other flat no-leads package.

According to an embodiment of the present disclosure, a leadframe for an integrated circuit (IC) device may comprise a center support structure for mounting an IC chip, a plurality of pins extending from the center support structure, and a bar connecting the plurality of pins remote from the center support structure. Each pin of the plurality of pins may include a dimple. The dimple of each pin may be disposed adjacent the bar. In some embodiments, the leadframe may be for a quad-flat no-leads IC package. In some embodiments, the leadframe may be for a dual-flat no-leads IC package. The leadframe may include a multitude of center support structures arrayed in a matrix for manufacturing multiple IC devices. In some embodiments, each dimple may extend from a first side of the bar to a second side of the bar. Each dimple may be etched into the respective pins in a square shape. Each dimple may be etched into the respective pins in a square shape with sides having a length of approximately 0.14 mm. Each dimple may be etched to a depth of approximately half the full height of the respective pin.

According to an embodiment of the present disclosure, a method for manufacturing an integrated circuit (IC) device in a flat no-leads package may include mounting an IC chip onto a center support structure of a leadframe, bonding the IC chip to at least some pins of the leadframe, encapsulating the leadframe and bonded IC chip creating an IC package, and cutting the IC package free from the bar by sawing through the encapsulated lead frame at a set of cutting lines intersecting the dimples of the plurality of pins. The leadframe may include a center support structure, a plurality of pins extending from the center support structure, and a bar connecting the plurality of pins remote from the center support structure. Each pin of the plurality of pins may include a dimple. Sawing along the set of cutting lines may expose an end face of each of the plurality of pins and leave a portion of the dimples that extends from the bottom surface of the IC package to a side surface with the exposed end faces of the pins. In some embodiments, the method may include performing an isolation cut to isolate individual pins of the IC package without separating the IC package from the lead frame and performing a circuit test of the isolated individual pins after the isolation cut. Some embodiments may include bonding the IC chip to at least some of the plurality of pins using wire bonding. Some embodiments may include plating the exposed portion of the plurality of pins, including the dimples, on a bottom surface of the IC package before cutting the IC package free from the bar.

According to another embodiment of the present disclosure, a method for installing an integrated circuit (IC) device in a flat no-leads package onto a printed circuit board (PCB) may include mounting an IC chip onto a center support structure of a leadframe, bonding the IC chip to at least some of the plurality of pins, encapsulating the leadframe and bonded IC chip creating an IC package, cutting the IC package free from the bar by sawing through the encapsulated lead frame at a set of cutting lines intersecting the dimples of the plurality of pins, and attaching the flat no-leads IC package to the PCB using a reflow soldering method to join the plurality of pins of the IC package to respective contact points on the PCB. Sawing along the set of cutting lines may expose an end face of each of the plurality of pins and leave a portion of the dimples that extends from the bottom surface of the IC package to a side surface with the exposed end faces of the pins. The leadframe may include a center support structure, a plurality of pins extending from the center support structure, and a bar connecting the plurality of pins remote from the center support structure. Each pin of the plurality of pins may include a dimple. Some embodiments of the method may include performing an isolation cut to isolate individual pins of the IC package without separating the IC package from the bar and performing a circuit test of the isolated individual pins after the isolation cut. Some embodiments of the method may include bonding the IC chip to at least some of the plurality of pins using wire bonding. Some embodiments of the method may provide provides fillet heights of approximately 60% of the exposed surface of the pins. Some embodiments of the method may include plating the exposed portion of the plurality of pins on a bottom surface of the IC package, including the dimples, before cutting the IC package free from the bar.

According to some embodiments of the present disclosure, an integrated circuit (IC) device in a flat no-leads package may include an IC chip mounted onto a center support structure of a leadframe and encapsulated with the leadframe to form an IC package having a bottom face and four sides, a set of pins with faces exposed along a lower edge of the four sides of the IC package, and a dimple in each of the set of pins disposed along a perimeter of the bottom face of the IC package and extending into the exposed faces of the set of pins. At least a bottom facing exposed portion of each of the plurality of pins including the dimple may be plated. In some embodiments, the plurality of pins may be attached to a printed circuit board with fillet heights of approximately 60%.

### BRIEF DESCRIPTION OF THE DRAWINGS

FIG. 1 is a schematic showing a cross section side view through an embodiment a flat no-leads package mounted on a printed circuit board (PCB) according to the teachings of the present disclosure.

FIG. 2A is a picture showing part of a typical QFN package in a side view and bottom view. FIG. 2B shows an enlarged view of the face of copper contact pins along the edge of QFN package exposed by sawing through an encapsulated leadframe.

FIG. 3 is a picture showing a typical QFN package after a reflow soldering process failed to provide sufficient mechanical and electrical connections to a PCB.

FIGS. 4A and 4B are pictures showing a partial view of a packaged IC device incorporating teachings of the present disclosure in a flat no-leads package with high wettable flanks for use in reflow soldering.

FIGS. 5A and 5B are drawings showing an isometric view of a typical QFN package after mounting to a PCB by a reflow soldering process.

FIGS. 6A and 6B are drawings showing a leadframe matrix including multiple leadframes which may be used to practice the teachings of the present disclosure.

FIGS. 7A and 7B are drawings showing a portion of the plurality of pins of two adjacent leadframes incorporating teachings of the present disclosure.

FIGS. 8A-8D show various embodiments of dimples and pins that may be used to practice the teachings of the present disclosure incorporating teachings of the present disclosure.

FIGS. 9A and 9B are drawings showing an isometric view of an encapsulated IC device incorporating the teachings of the present disclosure.

FIGS. 10A and 10B are drawings showing an isometric view of IC device and encapsulated in plastic attached to a PCB by a reflow soldering process according to teachings of the present disclosure.

FIG. 11 is a flowchart illustrating an example method for manufacturing an IC device in a flat no-leads package incorporating teachings of the present disclosure.

FIG. 12 illustrates an example process that may be used to practice teachings of the present disclosure.

### DETAILED DESCRIPTION

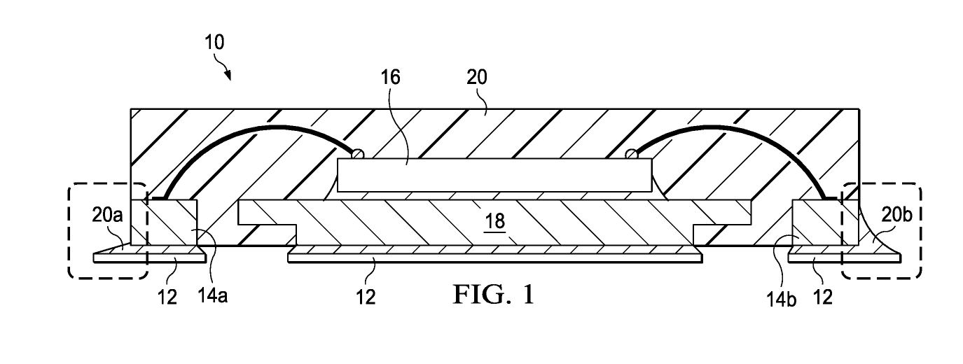

FIG. 1 is a side view showing a cross section view through a flat no-leads package 10 mounted on a printed circuit board (PCB) 12. Package 10 includes contact pins 14a, 14b, die 16, leadframe 18, and encapsulation 20. Die 16 may include any integrated circuit, whether referred to as an IC, a chip, and/or a microchip. Die 16 may include a set of electronic circuits disposed on a substrate of semiconductor material, such as silicon.

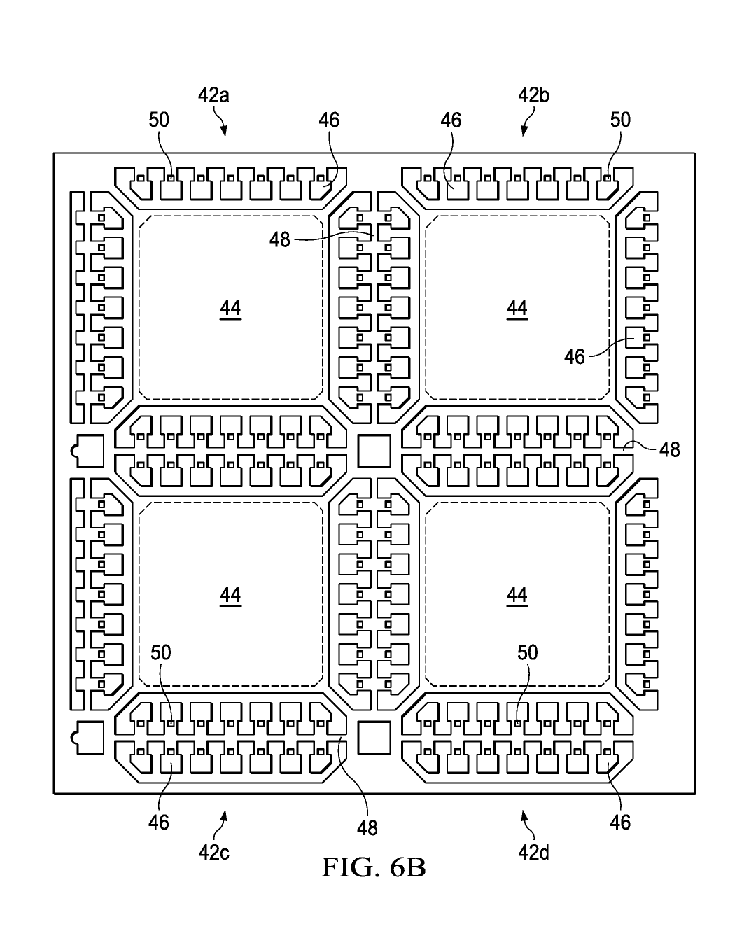

As shown in FIG. 1, contact pin 14a is the subject of a failed reflow process in which the solder 20a did not stay attached to the exposed face of contact pin 14a; the bare copper face of contact pin 14a created by sawing the package 10 free from a leadframe matrix (shown in more detail in FIG. 6 and discussed below) may contribute to such failures. In contrast, contact pin 14b shows an improved soldered connection 20b created by a successful reflow procedure. This improved connection provides both electrical communication and mechanical support. The face of contact pin 14b may have been plated before the reflow procedure (e.g., with tin plating).

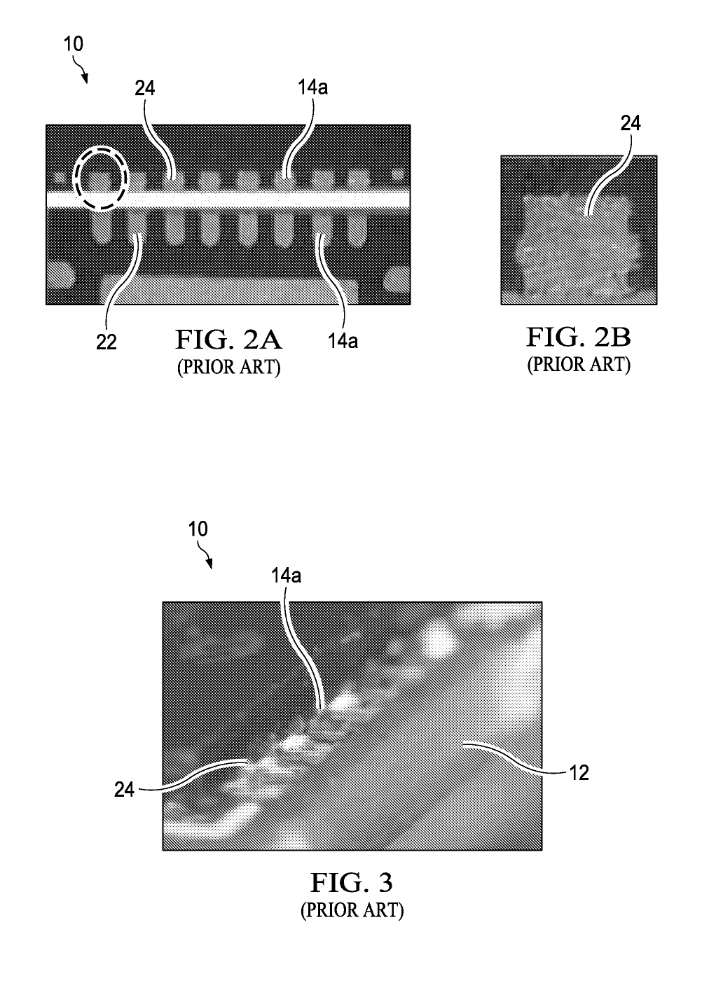

FIG. 2A is a picture showing part of a typical QFN package 10 in a side view and bottom view. FIG. 2B shows an enlarged view of the face 24 of copper contact pins 14a along the edge of QFN package 10 exposed by sawing through the encapsulated leadframe 18. As shown in FIG. 2A, the bottom 22 of contact pin 14a is plated (e.g., with tin plating) but the exposed face 24 is bare copper.

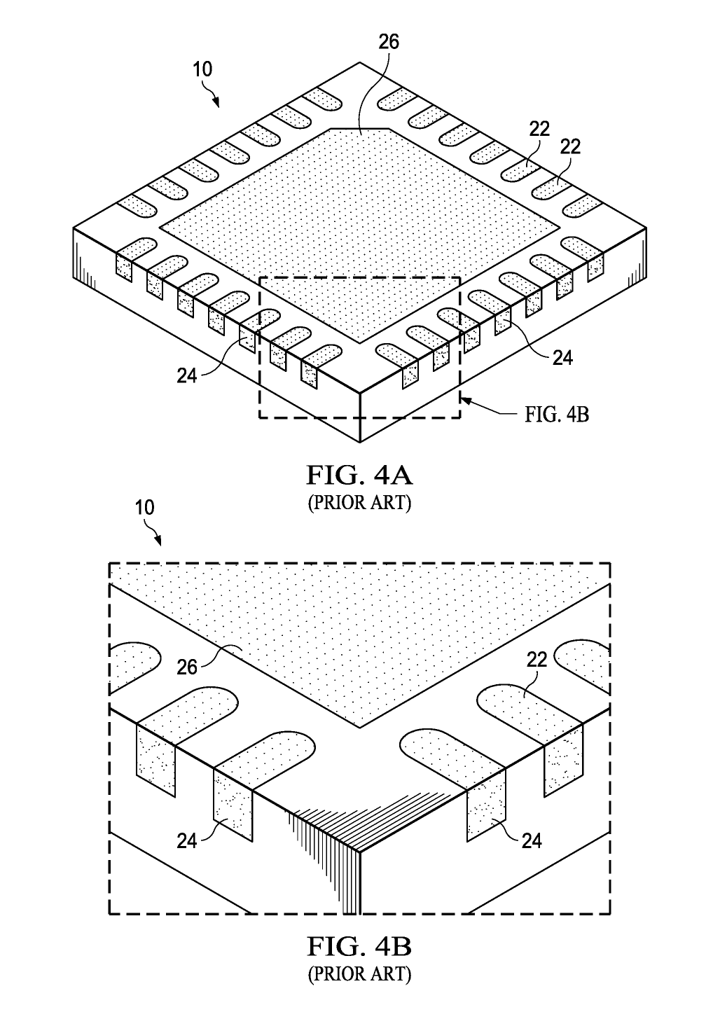

FIG. 3 is a picture of a typical QFN package 10 after a reflow soldering process failed to provide sufficient mechanical and electrical connections to a PCB 12. As shown in FIG. 3, bare copper face 24 of contact pins 14a may provide bad or no connection after reflow soldering. The exposed face 24 of contact pins 14a may not provide sufficient wettable flanks to provide a reliable connection.

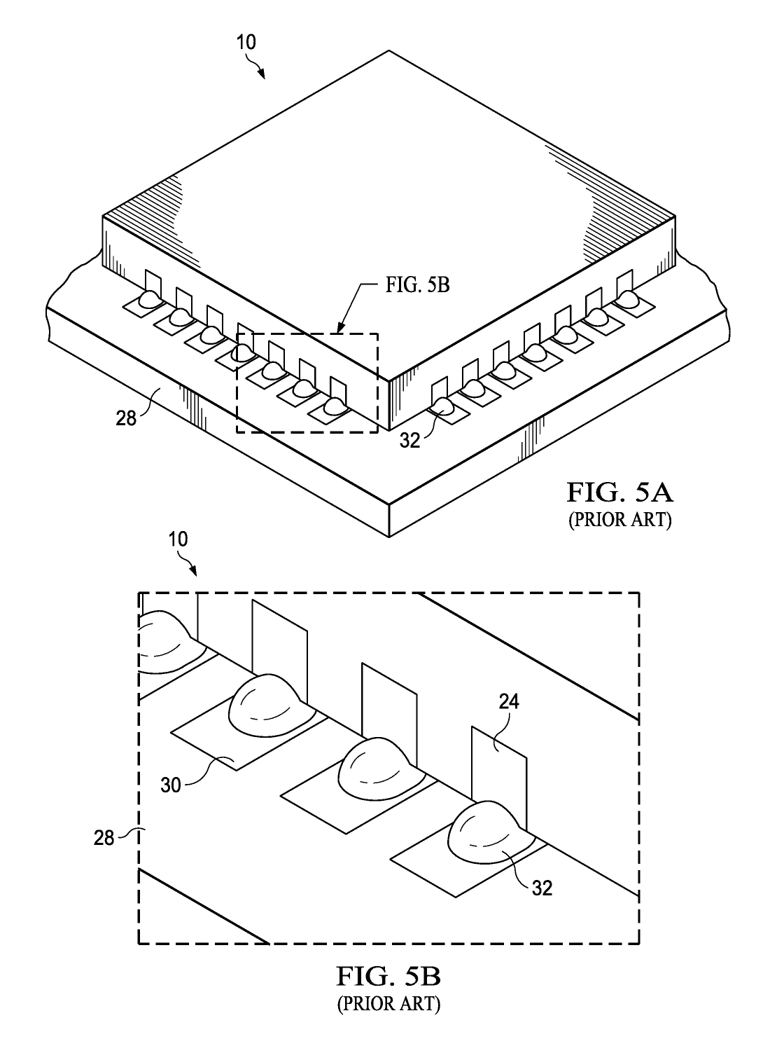

FIGS. 4A and 4B are drawings showing an isometric view of a typical QFN package 10 after sawing through the encapsulated leadframe 18. The bottom 22 of each contact pin 14a is plated (e.g., with tin plating), but the exposed face 24 of each contact pin is unplated due to the sawing process. In many QFN packages 10, there is an additional plated central surface such as thermal pad 26.

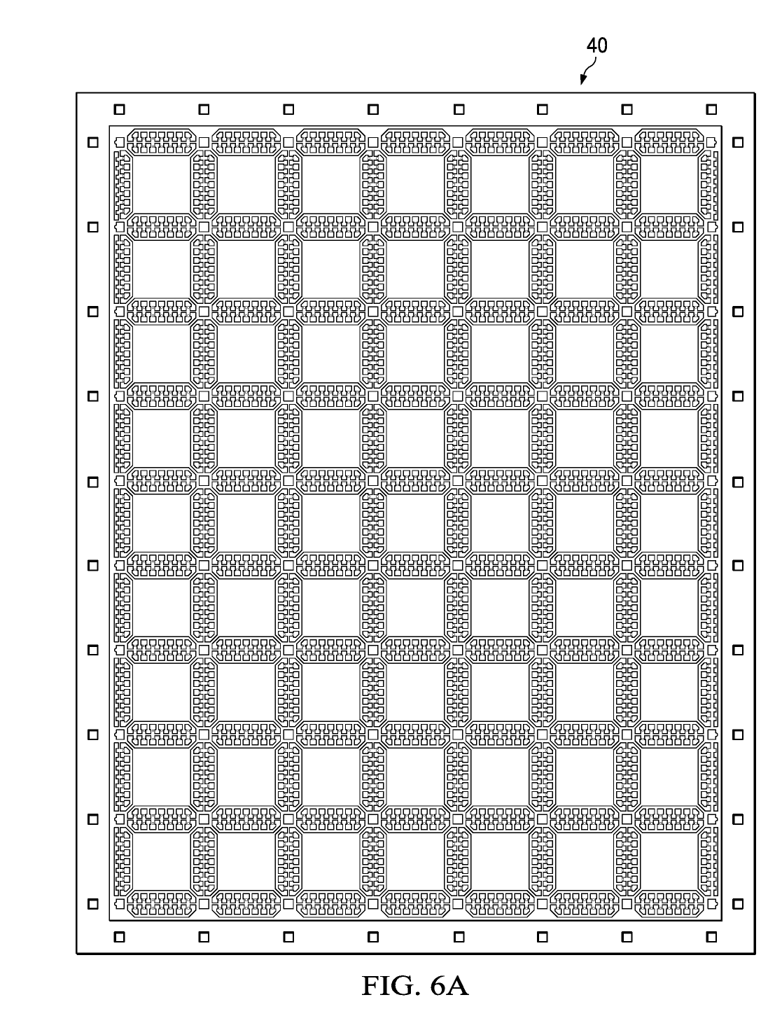

FIGS. 5A and 5B are drawings showing an isometric view of a typical QFN package 10 after mounting to a PCB 28 by a reflow soldering process. PCB includes leads 30, which are mechanically and electrically connected to the contact pins 14a by solder bead 32. As shown in FIGS. 5A and 5B, solder beads 32 cover only a small portion of exposed faces 24. As discussed above, this may be because of insufficient wettable flanks for the pins 14a.

FIGS. 6A and 6B are drawings showing a leadframe matrix 40 including multiple leadframes 42a, 42b, 42c, 42d which may be used to practice the teachings of the present disclosure. As shown, each leadframe 42 may include a center support structure 44, a plurality of pins 46 extending from the center support structure, and one or more bars 48 connecting the plurality of pins remote from the center support structure. Leadframe 42 may include a metal structure providing electrical communication through the pins 46 from an IC device (not shown in FIGS. 6A and 6B) mounted to center support structure 44 as well as providing mechanical support for the IC device. In some applications, an IC device may be glued to center support structure 44. In some embodiments, the IC device may be referred to as a die. In some embodiments, pads or contact points on the die or IC device may be connected to respective pins by bonding (e.g., wire bonding, ball bonding, wedge bonding, compliant bonding, thermosonic bonding, or any other appropriate bonding technique). In some embodiments, leadframe 42 may be manufactured by etching or stamping.

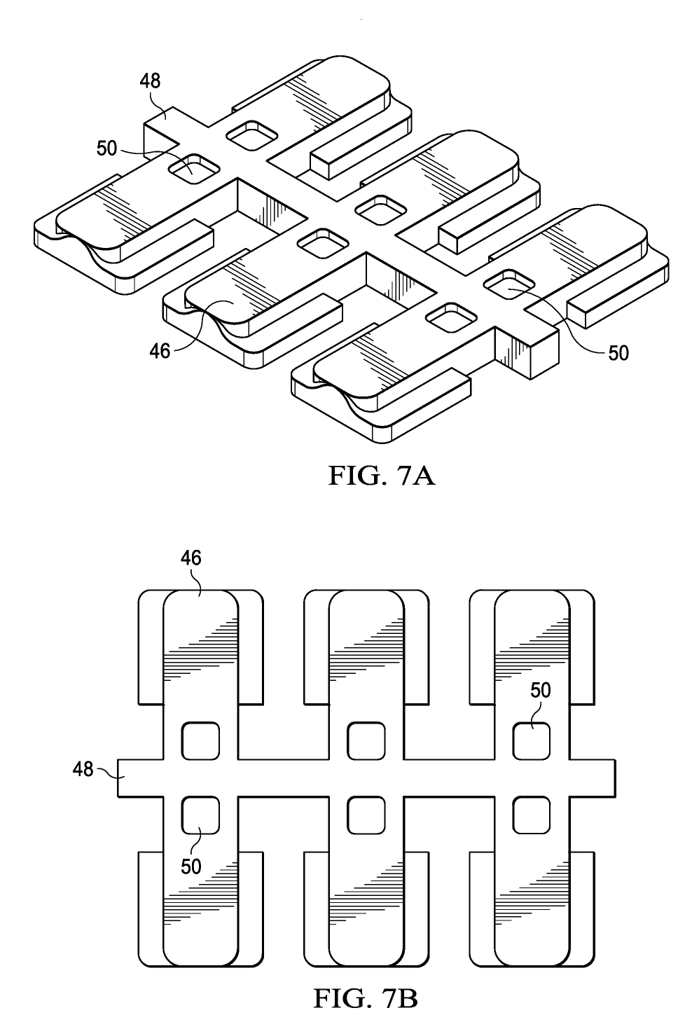

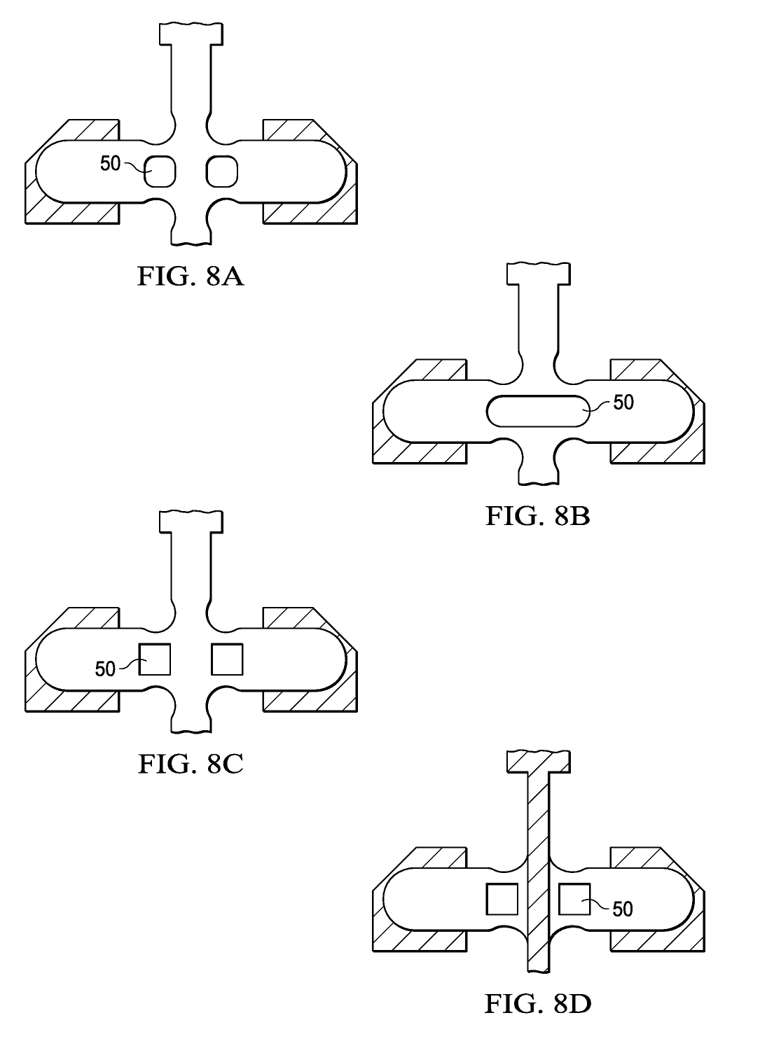

FIGS. 7A and 7B are drawings showing a portion of the plurality of pins 46 of two adjacent leadframes 42a, 42b. As shown in FIGS. 7A and 7B, the pins 46 may each include a dimple 50. In some embodiments of the present disclosure, dimples 50 may be etched into pins 46. In the embodiment of FIGS. 7A and 7B, dimples 50 may be square with a side length of approximately 0.14 mm and disposed on opposite sides of bar 48. In some embodiments, two opposing dimples 50 may be disposed with centers spaced approximately 0.075 mm from the edge of bar 48. In some embodiments, the center of opposing dimples 50 may be disposed approximately 0.3 mm apart. FIGS. 8A-8D show various embodiments of dimples 50 and pins 44 that may be used to practice the teachings of the present disclosure.

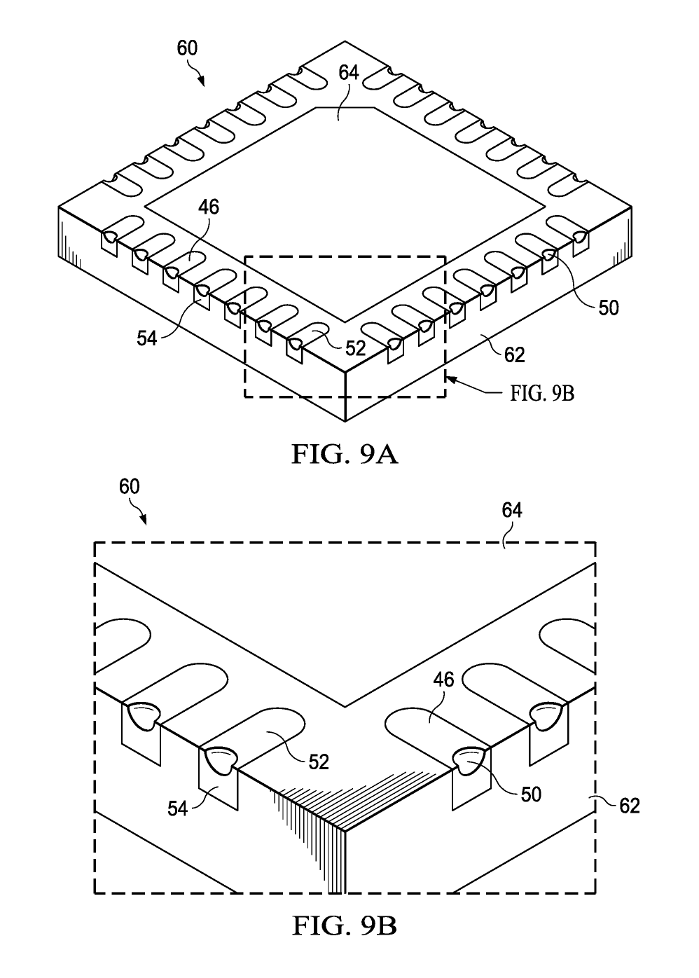

FIGS. 9A and 9B are drawings showing an isometric view of an encapsulated IC device 60 packaged in plastic 62 and incorporating the teachings of the present disclosure. The bottom surfaces 52 of the pins 46 and thermal pad 64 have been plated with tin to produce an IC device 60 in a flat no-leads package with high wettable flanks for use in reflow soldering, providing an improved solder connection such as that shown at contact pin 14b in FIG. 1. As shown, IC device 60 may comprise a quad-flat no-leads package. In other embodiments, IC device 60 may comprise a dual-flat no-leads packaging, or any other packaging (e.g., any micro leadframe (MLT)) in which the leads do not extend much beyond the edges of the packaging and which is configured to surface-mount the IC to a PCB.

As shown in FIGS. 9A and 9B, dimples 50 are plated along with bottom surfaces 52 of pins 46. Although the exposed faces 54 of pins 46 may include some bare copper, dimples 50 provide a plated surface on the side of IC device 60. The plated surface of dimples 50 provides increased wettable flanks and, therefore, may provide improved electrical and/or mechanical connections between IC device 60 and a PCB. In alternative embodiments, dimples 50 and/or bottom surfaces 52 may not be plated at all. In these embodiments, the physical shape of dimples 50 may allow solder to flow into dimples 50 and improve the connections even in the absence of plating.

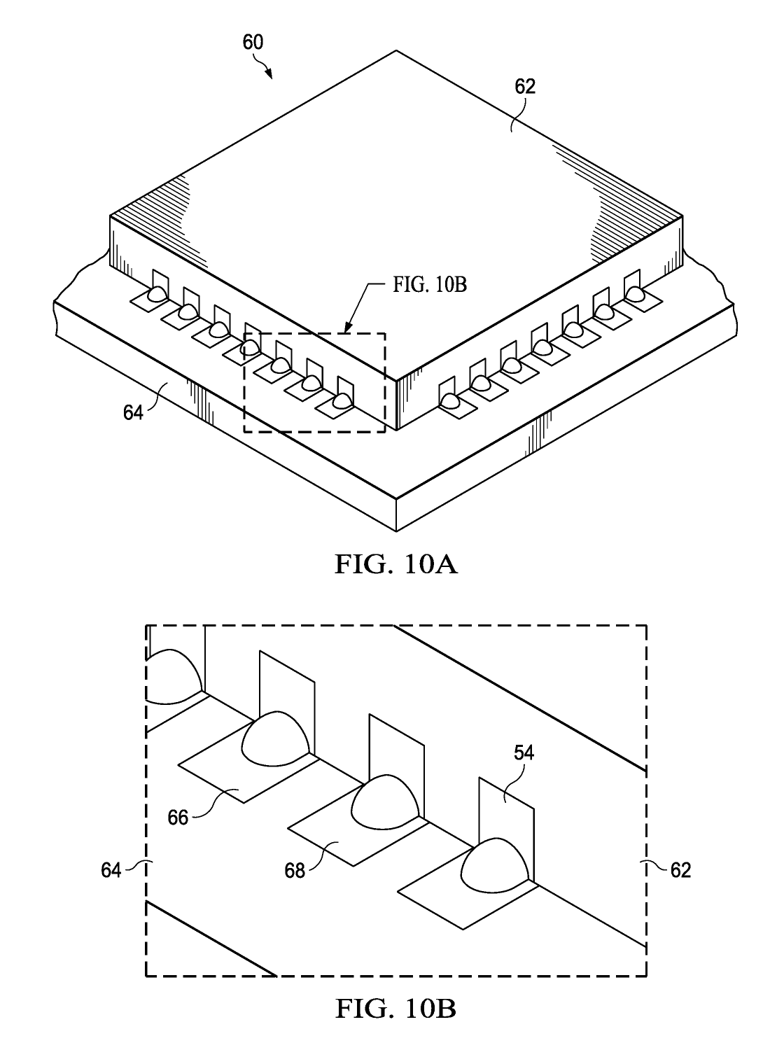

FIGS. 10A and 10B are drawings showing an isometric view of IC device 60 and encapsulated in plastic 62 attached to a PCB 64 by a reflow soldering process. As shown in FIGS. 10A and 10B, the pins 46 of IC device 60 are connected to leads 66 on PCB 64 by solder beads 68. In contrast to the IC device 10 shown in FIG. 5B, solder beads 68 extend upward along exposed faces 54 of pins 46. Greater physical extent of solder beads 68 upward along exposed faces 54 may provide improved mechanical and/or electrical connections between IC device 60 and PCB 64.

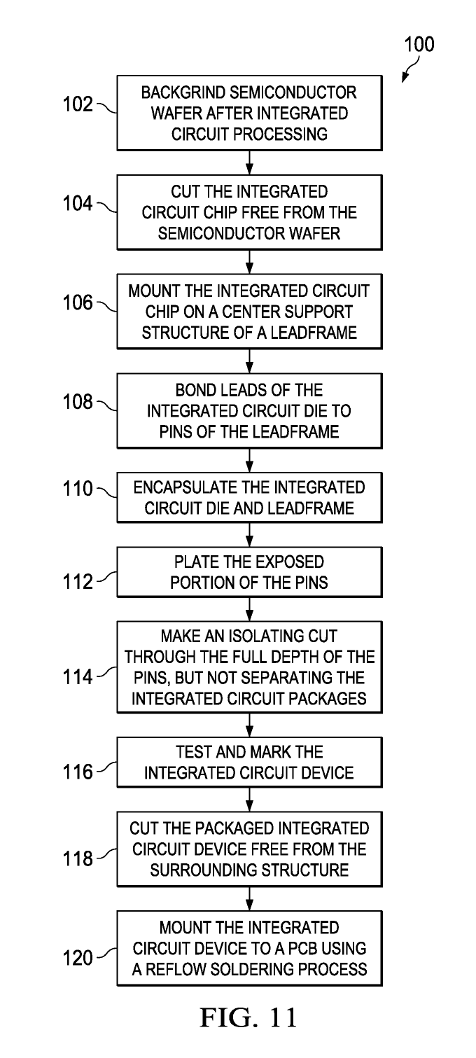

FIG. 11 is a flowchart illustrating an example method 100 for manufacturing an IC device in a flat no-leads package incorporating teachings of the present disclosure. Method 100 may provide improved connection for mounting the IC device to a PCB.

Step 102 may include backgrinding a semiconductor wafer on which an IC device has been produced. Typical semiconductor or IC manufacturing may use wafers approximately 750 μm thick. This thickness may provide stability against warping during high-temperature processing. In contrast, once the IC device is complete, a thickness of approximately 50 μm to 75 μm may be preferred. Backgrinding (also called backlap or wafer thinning) may remove material from the side of the wafer opposite the IC device.

Step 104 may include sawing and/or cutting the wafer to separate an IC chip from other components formed on the same wafer.

Step 106 may include mounting the IC chip (or die) on a center support structure of a leadframe. The IC die may be attached by the center support structure by gluing or any other appropriate method.

At Step 108, the IC die may be connected to the individual pins extending from the center support structure of the leadframe. In some embodiments, pads and/or contact points on the die or IC device may be connected to respective pins by bonding (e.g., wire bonding, ball bonding, wedge bonding, compliant bonding, thermosonic bonding, or any other appropriate bonding technique).

At Step 110, the IC device and leadframe may be encapsulated to form an assembly. In some embodiments, this includes molding into a plastic case. If a plastic molding is used, a post-molding cure step may follow to harden and/or set the housing.

Step 112 may include a chemical de-flashing and a plating process to cover the exposed bottom areas of the connection pins. As discussed above, the step of plating may not be incorporated in all embodiments of the present disclosure. In embodiments including plating, dimples in the pins may also be plated.

Step 114 may include performing an isolation cut. The isolation cut may include sawing through the pins of each package to electrically isolate the pins from one another.

Step 116 may include a test and marking of the IC device once the isolation cut has been completed. Method 100 may be changed by altering the order of the various steps, adding steps, and/or eliminating steps. For example, flat no-leads IC packages may be produced according to teachings of the present disclosure without performing an isolation cut and/or testing of the IC device. Persons having ordinary skill in the art will be able to develop alternative methods using these teachings without departing from the scope or intent of this disclosure.

Step 118 may include a singulation cut to separate the IC device from the bar, the leadframe, and/or other nearby IC devices in embodiments where leadframe 42 is part of a matrix 40 of leadframes 42a, 42b, etc. The singulation cut may be made through the dimples 50 of the pins 46 of the leadframe 42.

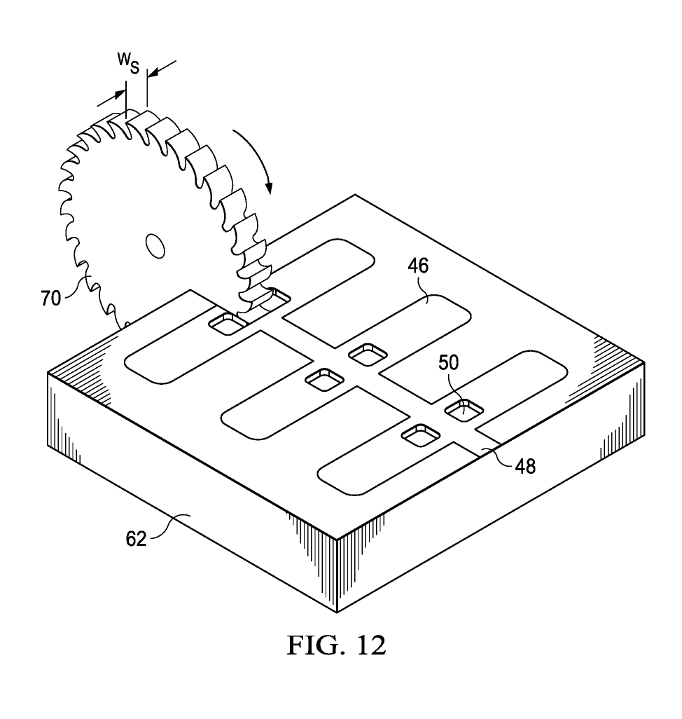

FIG. 12 illustrates a process of one embodiment of a singulation cut that may be used at Step 118. FIGS. 12 is a schematic drawing showing isometric view of saw 70 cutting through pins 46 along bar 48 encapsulated in plastic molding 62. After any testing and/or marking in Step 116, a singulation cut of width w_{f} is made through the full package as shown in FIG. 11. Saw width, wₛ, is wide enough to intersect dimples 50 but not so wide as to obliterate dimples 50 completely. Thus, after the singulation cut is complete, the remaining portion of dimples 50 will extend from bottom faces 52 to exposed faces 54 of pins 46 as shown in FIGS. 9A and 9B.

Step 120 may include attaching the separated IC device 60, in its package, to a PCB 64 or other mounting device. In some embodiments, the IC device may be attached to a PCB using a reflow soldering process. FIGS. 10A and 10B show an isometric view of the pin area of an IC device that has been mounted on a printed circuit board and attached by a reflow solder process. The dimples 50 provided by the present disclosure can increase the wettable flanks or fillet height to 60% and meet, for example, automotive customer requirements. Thus, according to various teachings of the present disclosure, the “wettable flanks” of a flat no-leads device may be improved and each solder joint made by a reflow soldering process may provide improved performance and/or increased acceptance rates during visual and/or performance testing.

In contrast, a conventional manufacturing process for a flat no-leads integrated circuit package may leave pin connections without sufficient wettable surface for a reflow solder process. Even if the exposed pins are plated before separating the package from the leadframe or matrix, the final sawing step used in a typical process leaves only bare copper on the exposed faces of the pins.

1-9. (canceled)

10. A method for manufacturing an integrated circuit (IC) device in a flat no-leads package, the method comprising:
mounting an IC chip onto a center support structure of a leadframe, the leadframe including:
the center support structure;
a plurality of pins extending from the center support structure; and
a bar connecting the plurality of pins remote from the center support structure;
wherein each pin of the plurality of pins includes a dimple;
bonding the IC chip to at least some of the plurality of pins;
encapsulating the leadframe and bonded IC chip creating an IC package; and
cutting the IC package free from the bar by sawing through the encapsulated lead frame at a set of cutting lines intersecting the dimples of the plurality of pins, exposing an end face of each of the plurality of pins and leaving a portion of the dimples that extends from the bottom surface of the IC package to a side surface with the exposed end faces of the pins.

11. A method according to claim 10, further comprising:
performing an isolation cut to isolate individual pins of the IC package without separating the IC package from the lead frame; and
performing a circuit test of the isolated individual pins after the isolation cut.

12. A method according to claim 10, further comprising bonding the IC chip to at least some of the plurality of pins using wire bonding.

13. A method according to claim 10, further comprising plating the exposed portion of the plurality of pins, including the dimples, on a bottom surface of the IC package before cutting the IC package free from the bar.

14. A method for installing an integrated circuit (IC) device in a flat no-leads package onto a printed circuit board (PCB), the method comprising:
mounting an IC chip onto a center support structure of a leadframe, the leadframe including:
the center support structure;
a plurality of pins extending from the center support structure; and
a bar connecting the plurality of pins remote from the center support structure;
wherein each pin of the plurality of pins includes a dimple;
bonding the IC chip to at least some of the plurality of pins;
encapsulating the leadframe and bonded IC chip creating an IC package; and
cutting the IC package free from the bar by sawing through the encapsulated lead frame at a set of cutting lines intersecting the dimples of the plurality of pins, exposing an end face of each of the plurality of pins and leaving a portion of the dimples that extends from the bottom surface of the IC package to a side surface with the exposed end faces of the pins; and
attaching the flat no-leads IC package to the PCB using a reflow soldering method to join the plurality of pins of the IC package to respective contact points on the PCB.

15. A method according to claim 14, further comprising:
performing an isolation cut to isolate individual pins of the IC package without separating the IC package from the bar; and
performing a circuit test of the isolated individual pins after the isolation cut.

16. A method according to claim 14, further comprising bonding the IC chip to at least some of the plurality of pins using wire bonding.

17. A method according to claim 14, wherein the reflow soldering process provides fillet heights of approximately 60% of the exposed surface of the pins.

18. A method according to claim 14, further comprising plating the exposed portion of the plurality of pins on a bottom surface of the IC package, including the dimples, before cutting the IC package free from the bar.

19-20. (canceled)

21. A method for manufacturing an integrated circuit (IC) device in a flat no-leads package, the method comprising:
mounting a plurality of IC chips onto respective center support structures of a leadframe assembly, the leadframe assembly comprising a plurality a center support structures arranged in a matrix, a plurality of pins associated with the center support structure; and a plurality of bars connecting pins associated with two adjacent center support structures, wherein each bar is arranged between two adjacent center support structures, wherein each pin of the plurality of pins includes a dimple;
bonding each IC chip to at least some of the plurality of pins;
encapsulating the leadframes and bonded IC chips; and
cutting the IC packages free from respective bars by sawing through the encapsulated lead frame at a cutting line chosen such that the a sawing blade intersects the dimples of pins of two adjacent IC packages, exposing an end face of each of the plurality of pins and leaving a portion of the dimples that extends from the bottom surface of the adjacent IC packages to a side surface with the exposed end faces of the pins.

22. A method according to claim 21, further comprising:
performing an isolation cut to isolate individual pins of the IC package without separating the IC package from the lead frame; and
performing a circuit test of the isolated individual pins after the isolation cut.

23. A method according to claim 21, further comprising bonding the IC chip to at least some of the plurality of pins using wire bonding.

24. A method according to claim 21, further comprising plating the exposed portion of the plurality of pins, including the dimples, on a bottom surface of the IC package before cutting the IC package free from the bar.

25. A method according to claim 21, wherein dimples on two adjacent pins associated with two center support structures are formed by an enlongated dimple that extends from a first of the two adjacent pins to a second one of the two adjacent pins.

26. A method according to claim 21, wherein the leadframe is for a quad-flat no-leads IC package.

27. A method according to claim 21, wherein the leadframe is for a dual-flat no-leads IC package.

28. A method according to claim 21, wherein each dimple is etched into the respective pins in a square shape.

29. A method according to claim 21, wherein each dimple is etched into the respective pins in a square shape with sides having a length of approximately 0.14 mm.

30. A method according to claim 21, wherein each dimple is etched to a depth of approximately half the full height of the respective pin.
